(19) United States
(12) Patent Application Publication
(10) Pub. No.: US 2025/0321261 A1
(43) Pub. Date: Oct. 16, 2025

(54) TEST AND MEASUREMENT INSTRUMENTS AND PROBES HAVING AN ISOLATED OUTPUT

(71) Applicant: Keithley Instruments, LLC, Solon, OH (US)

(72) Inventor: Gregory Sobolewski, Brecksville, OH (US)

(73) Assignee: Keithley Instruments, LLC, Solon, OH (US)

(21) Appl. No.: 19/170,601

(22) Filed: Apr. 4, 2025

Related U.S. Application Data
(60) Provisional application No. 63/633,492, filed on Apr. 12, 2024.

(51) Int. Cl. G01R 31/26; G01R 31/28

(52) U.S. Cl. CPC G01R 31/2621; G01R 31/2841

(57) ABSTRACT

The present disclosure describes a test and measurement system with a test and measurement instrument. In addition, the test and measurement system may include an isolation barrier providing galvanic isolation to the test and measurement instrument. The test and measurement system may include a circuit couplable to a device under test (DUT), where the circuit may include: a signal receiver configured to receive signals from the test and measurement instrument through the isolation barrier; an isolated power supply configured to power the circuit via the received signal; a signal generator configured to generate and output an isolated signal to the DUT using the isolated power supply; and a sensor for measuring output signals from the DUT in response to the isolated signal from the signal generator.

### CROSS-REFERENCE TO RELATED APPLICATIONS

This application is a nonprovisional and claims benefit of U.S. Provisional Application No. 63/633,492, titled “TEST AND MEASUREMENT INSTRUMENTS AND PROBES HAVING AN ISOLATED OUTPUT,” filed Apr. 12, 2024, the disclosure of which is incorporated herein by reference in their entirety.

### TECHNICAL FIELD

This disclosure relates to test and measurement instruments and probes, and more particularly to test and measurement instruments and probes having an electrically isolated output.

### BACKGROUND

High power device characterization, such as characterization of high power MOSFETs or IGBTs, requires multiple parameter measurements of devices under high voltage/high current switching conditions. Frequently those measurements are taken under very high common mode signal scenarios. Best-in-class approach employs test and measurement instruments, such as oscilloscopes, with probes that use isolation techniques to obtain measurements of voltage and current under such conditions. These probes provide galvanic isolation, e.g. using optical or RF isolation techniques, between a device under test (DUT) connected to an input of the probe and a test and measurement instrument connected to an output of the probe.

FIG. 1 illustrates a dynamic measurement platform for performing characterization of a DUT. As illustrated, FIG. 1 provides a two DUT: DUT_top and DUT_bottom. Critical measurements requiring use of probes with isolation techniques would include I_top, Inductor current, Gate_top voltage for example. Due to safety considerations, even measurement of signals such as Gate_bot might have to use probes with isolation techniques. Similarly, Vg_top signal generation on the DUT_top gate is subject to similar high common mode signal conditions. Again, even though Gate_bot might not be as susceptible to circuit switching currents, circuit switching currents also presents safety concerns due to scenarios involving device failure. A typical approach providing gate drive circuitry relies on magnetic coupling (transformers) which presents limited isolation impedance as well as potential safety limitations. High voltage requirements on new designs present severe constraints on isolation power circuit design.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a dynamic measurement platform for performing characterization of a DUT.

FIG. 2 illustrates a test and measurement system coupled to a device under test (DUT), with the test and measurement system utilizing isolation techniques, according to some examples.

FIG. 3 shows an example of a block diagram of the test and measurement system of FIG. 2, with further details with reference to the probe, according to some examples.

To facilitate understanding, identical reference numerals have been used, where possible, to designate identical elements that are common to the figures. It is contemplated that elements of one example may be beneficially incorporated in other examples.

### DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Examples herein describe a test and measurement system that provide common mode rejection and safety advantages over existing, transformer-based implementations. The present disclosure describes a test and measurement system having a test and measurement instrument and a probe with an isolation barrier disposed between the test and measurement instrument and the probe. The system described herein utilizes galvanic isolation techniques, according to embodiments of the disclosure, to provide common mode rejection and safety advantages over existing, transformer-based implementations.

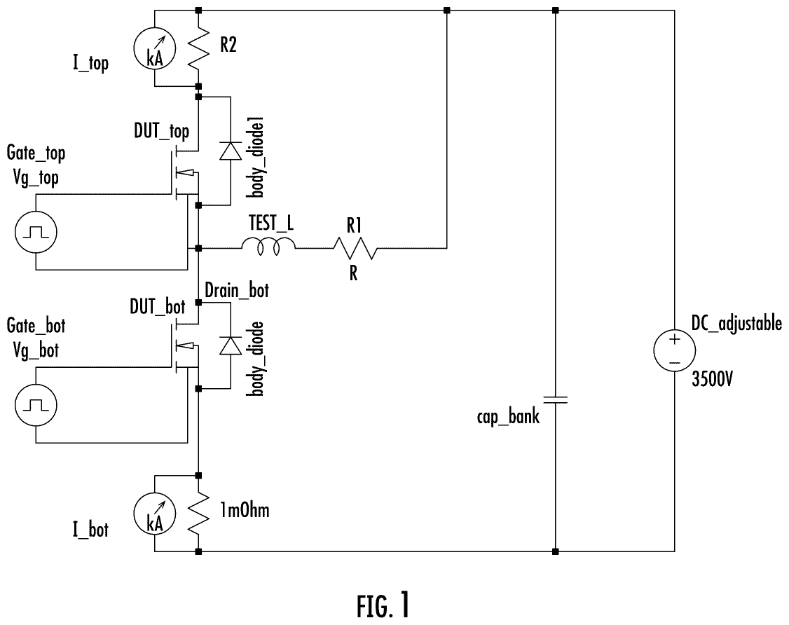

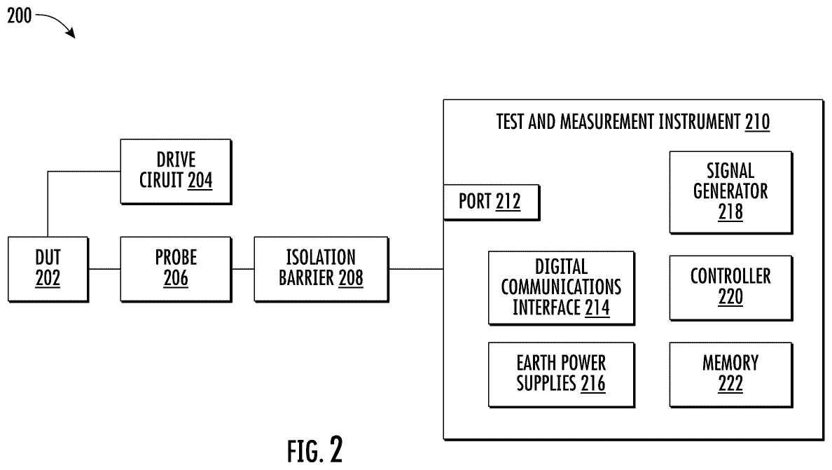

FIG. 2 illustrates a test and measurement system coupled to a device under test (DUT), with the test and measurement system utilizing isolation techniques, according to some examples. While a DUT 202 is included in FIG. 2, the test and measurement system 200 of FIG. 2 does not need to be coupled to a DUT 202. Instead, the test and measurement system 200 may be couplable to the DUT 202, and for illustrative purposes, the DUT 202 is coupled to the test and measurement system 200 of FIG. 2. In some examples, the DUT 202 is a metal-oxide semiconductor field effect transistor (MOSFET), and in such examples, the DUT 202 can be either DUT_top or DUT_bottom of FIG. 1. Further, in such examples, the drive circuit 204 shown in FIG. 2 can be the rest of the characterization platform of FIG. 1.

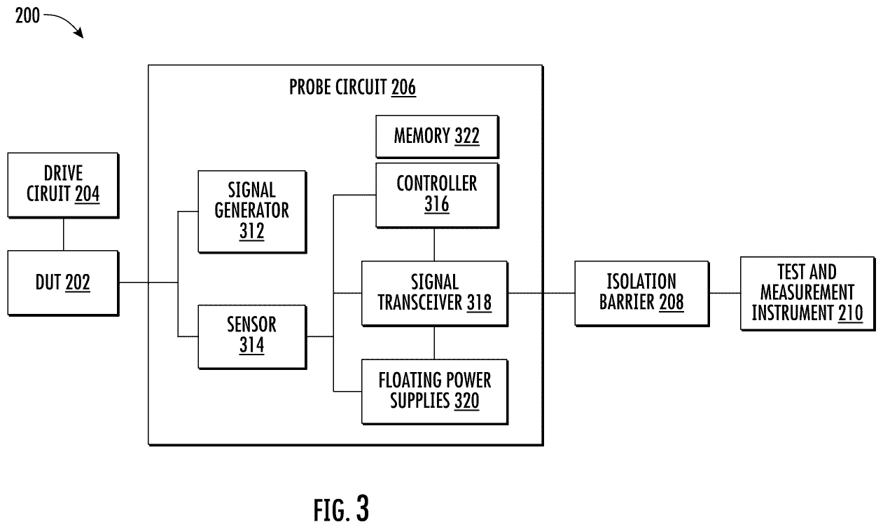

The test and measurement system 200 also includes a circuit 206 couplable to the DUT 202. In some examples, the circuit 206 is a probe, which is ultimately connected to a test and measurement instrument 210, such as an oscilloscope, according to some embodiments of the invention. For ease of reference, the circuit 206 may be referred herein as probe 206. In such examples, the circuit 206 can include two paths: a high accuracy, low speed digital path, and a high bandwidth path. Further discussion of the circuit 206 is provided herein with reference to FIG. 3.

The circuit 206 is also coupled to an isolation barrier 208 between the circuit 206 and the test and measurement instrument 210. Further discussion of the isolation barrier 208 is provided herein.

The test and measurement instrument 210 can be any test and measurement instrument, such as a source measure unit (SMU) or oscilloscope. While one test and measurement instrument 210 is illustrated in the test and measurement system 200, the test and measurement system 200 can include any number of test and measurement instruments. The test and measurement instrument 210 of the test and measurement system 200 is couplable to any terminal of a DUT 202. In some examples, the test and measurement instrument 210 of the test and measurement system 200 can be couplable to multiple terminals of the DUT 202 and can be couplable to any number of DUTs.

As illustrated in FIG. 2, the test and measurement instrument 210 includes a port 212 to couple to the probe 206 and/or isolation barrier 208. The test and measurement instrument 210 also includes a digital communications interface 214, a signal generator 218, a controller 220, and Earth ground-based power supplies 216.

In some examples, the controller 220 may include one or more processors configured to execute instructions from memory 222 and may perform any methods and/or associated steps indicated by such instructions, such as instructing the digital communications interface 214, the signal generator 218, and/or the Earth ground-based power supplies 216. Memory 222, which represents any memory in the test and measurement instrument 210, may be implemented as processor cache, random access memory (RAM), read only memory (ROM), solid state memory, hard disk drive(s), or any other memory type. Memory 222 acts as a medium for storing data, computer program products, and other instructions. User interface (not illustrated) receives user inputs that are coupled to the controller 220. User inputs may include a keyboard, mouse, trackball, touchscreen, and/or any other controls employable to allow a user to interact with a GUI on display (not illustrated). The display (not illustrated) may be a digital screen or any other monitor to display waveforms, measurements, and other data to a user. While the components of the test and measurement instrument 210 are depicted as being integrated within test and measurement instrument 210, it will be appreciated by a person of ordinary skill in the art that any of these components can be external to the test and measurement instrument 210 and can be coupled to the test and measurement instrument 210 in any conventional manner.

Under instruction from the controller 220, the signal generator 218 and the digital communications interface 214 work in tandem to provide signals through the isolation barrier 208 and the probe 206 to the DUT 202. These signals can be radio-frequency (RF) signals, optical signals, or other signals that can bypass galvanic isolation of the isolation barrier 208. In some examples, these signals can be used for power and/or digital communication. The components of the test and measurement instrument 210 can be powered by the Earth ground-based power supplies 216. In some examples, the Earth ground-based power supplies comprises power supplies for powering the components of the test and measurement instrument 210 while being coupled to Earth ground.

As described herein, the test and measurement system 200 of FIG. 2 is used to drive the DUT 202 along with the drive circuit 204 coupled to the DUT 202. Specifically, the test and measurement system 200 of FIG. 2 can be used with a drive circuit 204, such as the characterization platform of FIG. 1, for driving a gate of a MOSFET. In doing so, the test and measurement system 200 of FIG. 2 can provide common mode rejection and high voltage isolation for a DUT 202.

FIG. 3 shows an example of a block diagram of the test and measurement system 200 of FIG. 2, with further details with reference to the probe. The DUT 202, the drive circuit 204, the isolation barrier 208, the probe 206, and the test and measurement instrument 210 of FIG. 3 are the same DUT 202, drive circuit 204, isolation barrier 208, probe 206, and test and measurement instrument 210 of FIG. 2; however, FIG. 3 provides further details for the probe 206 of FIG. 2. While one probe is illustrated with reference to FIG. 2 and FIG. 3, the test and measurement system 200 can include any number of probes and thus any number of channels for testing the DUT 202. If more than one channel is used, synchronization between channels can be done on the test and measurement instrument 210 with its earth ground-based power supplies 216. In other examples, synchronization between channels can be done with a digital signal source (not illustrated) in the probe 206. Timing synchronization between channels can be carried out leveraging techniques from probes with isolation technology.

In examples with multiple channels, the test and measurement system 200 can include a second probe or a second sensor. In such examples, the second sensor can be used on a second DUT and similar to the functionality of probe 206, can measure output signals from the second DUT. In examples, the second sensor and/or second probe can have similar features as probe 206 with regard to a second DUT.

As illustrated FIG. 3, the probe 206 includes a signal generator 312, a sensor 314, a signal transceiver 318, floating power supplies 320, and a controller 316. The signal transceiver 318 receives signals from the test and measurement instrument 210 through the isolation barrier 208. These signals can be RF signals or laser signals, and accordingly these signals can pass through the isolation barrier 208. These signals received can be used for power, data, control, or other type of communication between the test and measurement instrument 210 and the probe 206. For power signals received by the probe 206, the power signals are provided to the floating power supplies 320. In some examples, the floating power supplies 320 capture these power signals to provide power to the rest of the components of the probe 206. With the power from the floating power supplies 320, the signal generator 312 can generate measurement signals to send to the DUT 202, and in response, the sensor 314 can make measurements of the DUT 202 in response to the measurement signals sent to the DUT 202. In some examples, the signal generator 312 and the signal transceiver 318 can be implemented as a single component.

The pathway between the test and measurement instrument 210 through the isolation barrier 208 to the probe 206 operates between the digital communications interface 214 of the test and measurement instrument 210 and the signal transceiver 318 of the probe 206. This pathway can be a conductor or, preferably, an optical fiber. This pathway can be a wireless or radio frequency (RF) communication link. An optical fiber communication link provides complete galvanic isolation to the test and measurement equipment it is connected to and ultimately from earth ground. Accordingly, in some examples, the pathway between the test and measurement instrument 210 to the probe 206 includes the isolation barrier 208. Further, increasing the length of the optical fiber communication link allows the probe 206 to be connected to higher common-mode voltages with respect to earth ground.

Controller 316 communicates with the signal generator 312 as well as with a signal transceiver 318. In some examples, the signal transceiver 318 is a digital communication interface between the controller 316 and controller 220 through the communication link between the test and measurement instrument 210 and the probe 206. The sensor 314 in some examples includes an analog-to-digital converter (not illustrated) and sends the digitized measurement to the controller 316. In some examples, the sensor 314 can be a digital multimeter, a digital voltmeter, or some other measurement device for the DUT 202. Then, the controller 316 sends the digitized measurement to the signal transceiver 318, which is then relayed to the test and measurement instrument 210 through the isolation barrier 208.

In some examples, the controller 316 may include one or more processors configured to execute instructions from memory 322 and may perform any methods and/or associated steps indicated by such instructions, such as instructing the signal generator 312, the signal transceiver 318, the sensor 314, and/or the floating power supplies 320. Memory 322, which represents any memory in the test and measurement instrument 210, may be implemented as processor cache, random access memory (RAM), read only memory (ROM), solid state memory, hard disk drive(s), or any other memory type. Memory 322 acts as a medium for storing data, computer program products, and other instructions.

In some examples, a measured input signal from the DUT 202 and the output drive signal to the DUT 202 does not have to be isolated from each other. The probe 300 may include only a high accuracy, digital path, which is galvanically isolated from controller 316 and earth ground,

In some examples, the floating power supplies 320 comprise a capacitor bank or other type of power source. The floating power supplies 320 can comprise an optically, e.g. laser (or different frequency electro-magnetic (EM) radiation), isolated power supply, which may enable capabilities that are not available on the market today. The floating power supplies 320 may be based on local storage bank with minimal inductance to deliver drive to the gate of the DUT 202. In some examples, the probe 206 with the isolated power supply 320 and the drive circuit 204 can be implemented in an output channel of the test and measurement instrument 210, such as an “aux out” channel of an oscilloscope, or a “source” output of a source measure unit (SMU), for example, and/or could be implemented in output circuitry of a test and measurement probe.

In an example including optical implementation, power delivery to the gate of the DUT 202 may be limited by the laser or equivalent delivery source. However, the power delivery to the gate of the DUT 202 may be sufficient with the power signals received through the isolation barrier 208 and corresponding power captured with the floating power supplies 320 as DUT characterization does not require constant power delivery. Because average power needs to drive gate of DUT 202 are rather low, power delivery of the probe 206 may be sufficient even with such extended capability.

Even though the discussion above is somewhat specific to high power device characterization, embodiments of the disclosure include general signal generation needs requiring very high common mode rejection and high voltage isolation.

The test and measurement system described herein allows for complete galvanic isolation between the probe and the test equipment, such as an oscilloscope or an SMU, connected to the probe. When a communication link is used for an isolation barrier, the bridging coupling across this barrier is very small which enables high common-mode rejection from direct current (DC) to very high bandwidths to be achieved. This allows the user to make non-ground referenced measurements and eliminates the potential for circulating currents to develop forming “ground-loops” which degrade the accuracy and signal fidelity of the measurement. The probes of the disclosed technology are capable of measuring signals on top of large common-mode voltages.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement system, including: a test and measurement instrument; an isolation barrier providing galvanic isolation to the test and measurement instrument; and a circuit couplable to a device under test (DUT), where the circuit may include: a signal receiver configured to receive signals from the test and measurement instrument through the isolation barrier; an isolated power supply configured to power the circuit via the received signal; a signal generator configured to generate and output an isolated signal to the DUT using the isolated power supply; and a sensor for measuring output signals from the DUT in response to the isolated signal from the signal generator.

Example 2 is the test and measurement system of Example 1, where the DUT is a metal-oxide semiconductor field-effect transistor (MOSFET), and the circuit is coupled to two terminals of the MOSFET.

Example 3 is the test and measurement system of Example 1 or Example 2, where the circuit is coupled to a gate of the MOSFET.

Example 4 is the test and measurement system of any one of Example 1-3, where the circuit is a probe.

Example 5 is the test and measurement system of any one of Example 1-4, where the test and measurement instrument may include a signal generator configured to generate and transmit signals to the circuit over the isolation barrier to power the circuit.

Example 6 is the test and measurement system of any one of Example 1-5, where the signal generator is configured to communicate with the circuit through the isolation barrier.

Example 7 is the test and measurement system of any one of Example 1-6, where the signals received by the signal receiver are used as power for the isolated power supply.

Example 8 is the test and measurement system of any one of Example 1-7, where the signals received utilize either laser or radio-frequency (RF) energy.

Example 9 is the test and measurement system of any one of Example 1-8, further including a gate drive circuit coupled to the DUT.

Example 10 is the test and measurement system of any one of Example 1-9, where the signal receiver is a signal transceiver configured to receive laser power delivery from the test and measurement instrument through the isolation barrier.

Example 11 is the test and measurement system of any one of Example 1-10, where the isolated power supply is configured to have a duty cycle based on the power delivered by the signals received over the signal receiver.

Example 12 is the test and measurement system of any one of Example 1-11, where the isolated power supply may include capacitors to store energy to power the circuit.

Example 13 is the test and measurement system of any one of Example 1-12, where the isolation barrier provides high voltage isolation.

Example 14 is the test and measurement system of any one of Example 1-13, where the isolation barrier implements high impedance.

Example 15 is the test and measurement system of any one of Example 1-14, further including where the test and measurement instrument may include Earth ground-based power supplies.

Example 16 is the test and measurement system of any one of Example 1-15, where: the sensor is a first sensor; the DUT is a first DUT; the isolated signal is a first isolated signal; the output signals are first output signals; the circuit is couplable to a second DUT and is configured to generate and output a second isolated signal to the DUT using the isolated power supply; and the circuit further may include a second sensor for measuring second output signals from the second DUT in response to the second isolated signal from the signal generator.

Example 17 is the test and measurement system of any one of Example 1-16, where the test and measurement instrument is configured to synchronize measurements of the second output signals and measurements of the first output signals.

Example 18 is the test and measurement system of any one of Example 1-17, where the test and measurement instrument is an oscilloscope or a source measure unit (SMU).

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

1. A test and measurement system, comprising:
a test and measurement instrument;
an isolation barrier providing galvanic isolation to the test and measurement instrument; and
a circuit couplable to a device under test (DUT), wherein the circuit comprises:
a signal receiver configured to receive signals from the test and measurement instrument through the isolation barrier;
an isolated power supply configured to power the circuit via the received signal;
a signal generator configured to generate and output an isolated signal to the DUT using the isolated power supply; and
a sensor for measuring output signals from the DUT in response to the isolated signal from the signal generator.

2. The test and measurement system of claim 1, wherein the DUT is a metal-oxide semiconductor field-effect transistor (MOSFET), and the circuit is coupled to two terminals of the MOSFET.

3. The test and measurement system of claim 2, wherein the circuit is coupled to a gate of the MOSFET.

4. The test and measurement system of claim 1, wherein the circuit is a probe.

5. The test and measurement system of claim 1, wherein the test and measurement instrument comprises a signal generator configured to generate and transmit signals to the circuit over the isolation barrier to power the circuit.

6. The test and measurement system of claim 5, wherein the signal generator is configured to communicate with the circuit through the isolation barrier.

7. The test and measurement system of claim 1, wherein the signals received by the signal receiver are used as power for the isolated power supply.

8. The test and measurement system of claim 1, wherein the signals received utilize either laser or radio-frequency (RF) energy.

9. The test and measurement system of claim 1, further comprising a gate drive circuit coupled to the DUT.

10. The test and measurement system of claim 1, wherein the signal receiver is a signal transceiver configured to receive laser power delivery from the test and measurement instrument through the isolation barrier.

11. The test and measurement system of claim 1, wherein the isolated power supply is configured to have a duty cycle based on the power delivered by the signals received over the signal receiver.

12. The test and measurement system of claim 1, wherein the isolated power supply comprises capacitors to store energy to power the circuit.

13. The test and measurement system of claim 1, wherein the isolation barrier provides high voltage isolation.

14. The test and measurement system of claim 1, wherein the isolation barrier implements high impedance.

15. The test and measurement system of claim 1, further comprising wherein the test and measurement instrument comprises Earth ground-based power supplies.

16. The test and measurement system of claim 15, wherein:
the sensor is a first sensor;
the DUT is a first DUT;
the isolated signal is a first isolated signal;
the output signals are first output signals;
the circuit is couplable to a second DUT and is configured to generate and output a second isolated signal to the DUT using the isolated power supply; and
the circuit further comprises a second sensor for measuring second output signals from the second DUT in response to the second isolated signal from the signal generator.

17. The test and measurement system of claim 16, wherein the test and measurement instrument is configured to synchronize measurements of the second output signals and measurements of the first output signals.

18. The test and measurement system of claim 1, wherein the test and measurement instrument is an oscilloscope or a source measure unit (SMU).
